(19) United States
(12) Patent Application Publication
(10) Pub. No.: US 2011/0254900 A1
(43) Pub. Date: Oct. 20, 2011

(54) Inkjet head assembly and method for manufacturing the same

(75) Inventors: Pil Joong Kang, Suwon (KR); Chang Sung Park, Suwon (KR); Jae Woo Joung, Suwon (KR); Chung Mo Yang, Ansan (KR)

(73) Assignee: SAMSUNG ELECTRO-MECHANICS CO., LTD., Suwon-si (KR)

(21) Appl. No.: 13/064,571

(22) Filed: Mar. 31, 2011

(30) Foreign Application Priority Data
Apr. 16, 2010 (KR) 10-2010-0035285

(51) Int. Cl. B41J 2/045; H01L 21/302

(52) U.S. Cl. 347/71; 438/21; 257/E21.214

(57) ABSTRACT

There is provided an inkjet head assembly that includes: an inkjet head plate including an ink path; a piezoelectric actuator facing a pressure chamber in the inkjet head plate and providing driving force for ejecting ink to a nozzle from the pressure chamber; a package part stacked on the inkjet head plate and including a path moving ink introduced from the outside to an inlet of the inkjet head plate; and an electrical connector filling a via penetrating the package part and electrically connected with the piezoelectric actuator.

### CROSS-REFERENCE TO RELATED APPLICATIONS

This application claims the priority of Korean Patent Application No. 10-2010-0035285 filed on Apr. 16, 2010, in the Korean Intellectual Property Office, the disclosure of which is incorporated herein by reference.

### BACKGROUND OF THE INVENTION

1. Field of the Invention

The present invention relates to an inkjet head assembly, and more particularly, to an inkjet head assembly and a manufacturing the same that can densify an inkjet head by minimizing a dimension required to mount the inkjet head by enhancing an connection mechanism between electrical wires for operating a piezoelectric actuator and an ink storage tank supplying ink.

2. Description of the Related Art

In general, an inkjet head is a structure which ejects ink in a droplet form through a small nozzle by converting an electrical signal into physical force. The inkjet head may be divided into two types in accordance with an ink ejection method. One of two types is a thermally driven type inkjet head that generates bubbles in ink and ejects ink by the expansion force of the bubbles, while the other of the two types is a piezoelectric type inkjet head that uses a piezoelectric body and ejects ink by pressure applied to ink due to deformation of the piezoelectric body.

In particular, the piezoelectric type inkjet head has been widely used in an industrial inkjet printer in recent years. For example, a circuit pattern is directly formed by jetting ink acquired by melting a metal such as gold, silver, or the like, onto an flexible printed circuit board (FPCB) or the piezoelectric type inkjet head is used for industrial graphics or for manufacturing of an liquid crystal display (LCD), an organic light emitting diode (OLED), a solar cell, and the like.

An ink storage tank is required to supply ink to the inkjet head and in general, the ink jet head is manufactured by an MEMS process of silicon, while the ink storage tank is manufactured by mechanical processing. In the case of the silicon processing, a process tolerance is tens of μm, while in the general mechanical processing, the process tolerance is minimally hundreds of μm to several mm depending on a property and a processing method of a structure, a dimension required to connect the inkjet head and the ink storage tank with each other may be large, thereby increasing an entire width of the inkjet head.

In general, since the inkjet head is manufactured at a wafer level, when the entire width of the inkjet head is increased, the number of manufacturable inkjet heads is decreased by a single wafer, thereby causing deterioration of productivity such as a decrease of processing yield and an increase of manufacturing costs.

Further, since it is important for the inkjet printer to have high productivity by mounting how many inject heads in recent years, it is a core technology to configure the inkjet head in an array type and for this, the width of the inkjet head needs to be thin. Accordingly, an increase in the width of the inkjet head makes it difficult to implement the structure of the array-type inkjet head.

### SUMMARY OF THE INVENTION

An aspect of the present invention provides an inkjet head assembly which is manufacturable with a wafer-level package by making a connection structure of an ink storage tank simply by using a via-fill wire as an electrical wire of an inkjet head assembly and a manufacturing method thereof.

Another aspect of the present invention also provides an inkjet head assembly having improved productivity such as an increase of processing yield and a saving in manufacturing costs by increasing the number of manufacturable inkjet heads in a single wafer by reducing the entire width of the inkjet head and a manufacturing method thereof.

Another aspect of the present invention provides an inkjet head assembly which can be formed in an array-type structure of the inkjet head by reducing a mounting dimension of the inkjet head and a manufacturing method thereof.

According to an aspect of the present invention, there is provided an inkjet head assembly that includes: an inkjet head plate including an ink path; a piezoelectric actuator facing a pressure chamber in the inkjet head plate and providing driving force for ejecting ink to a nozzle from the pressure chamber; a package part stacked on the inkjet head plate and including a path moving ink introduced from the outside to an inlet of the inkjet head plate; and an electrical connector filling a via penetrating the package part and electrically connected with the piezoelectric actuator.

Further, the inkjet head assembly may further include a connection member electrically connecting the piezoelectric actuator with the electrical connector. The connection member may be formed by a solder ball.

In addition, the inkjet head assembly may further include a polymer film provided on the piezoelectric actuator and preventing the overflow of the solder ball. The polymer film may be a photosensitive polymer (photoresist).

The connection member of the inkjet head assembly may be an anisotropic conductive film (ACF) or a solder bump.

The via of the inkjet head assembly may have a shape of a vertical hole having a predetermine diameter or a shape of an inclined hole having a diameter gradually increasing towards the bottom from the top of the package part.

The via of the inkjet head assembly maybe a through-hole formed by deep reaction-ion etching (DRIE).

The package part of the inkjet head assembly may be formed by a single crystal silicon wafer or an SOI wafer.

Further, the inkjet head assembly may further include an intermediate layer bonding the package part and the inkjet head plate to each other. The intermediate layer may be formed by a glass wafer or a silicon wafer.

The intermediate layer of the inkjet head assembly may include: a receiver receiving the top of the piezoelectric actuator; and a communication hole being in communication with the receiver and the via.

The receiver of the inkjet head assembly may be a groove concaved towards the top from the bottom of the intermediate layer, and may have a shape corresponding to the shape of the piezoelectric actuator and have a depth equal to a value acquired by adding the thickness of the piezoelectric actuator to a processing error.

Further, the inkjet head assembly may further include a conductive film formed on the package part and connecting the electrical connector with an external power supply applying voltage to the piezoelectric actuator.

A cross-section of the electrical connector may have a 1 shape, a T shape, or an I-beam shape.

In addition, the inkjet head assembly may further include an oxide film formed on the top and bottom of the package part and a portion where the via is formed.

According to another aspect of the present invention, there is provided an inkjet head assembly that includes: an inkjet head plate including an ink path; a piezoelectric actuator facing a pressure chamber in the inkjet head plate and providing driving force for ejecting ink to a nozzle from the pressure chamber; a package part constituted by a silicon layer where a via penetrating the top and bottom and a glass layer bonding the silicon layer and the inkjet head plate to each other, and moving ink introduced from the outside to an inlet of the inkjet head plate; and an electrical connector filled in the via and electrically connected with the piezoelectric actuator.

According to yet another aspect of the present invention, there is provided a method for manufacturing an inkjet head assembly that includes: forming an ink path in an inkjet head plate; forming a piezoelectric actuator providing driving force for ejecting ink to a nozzle in a pressure chamber of the inkjet head plate to face the pressure chamber; processing a package part to include a path moving ink introduced from the outside to an inlet of the inkjet head plate and a via penetrating the top and bottom; forming an electrical connector in the via to electrically connect with the piezoelectric actuator; and stacking and bonding the package part onto the inkjet head plate.

The processing of the package part may form the path and the via by etching a silicon wafer.

The processing of the package part may etch the via to have a shape of a vertical hole having a constant diameter or an inclined hole having a diameter gradually increasing toward the bottom of the package part.

The processing of the package part may form the path and the via by a deep reactive-ion etching (DRIE) process.

Further, the method may further include: processing an intermediate layer to form a communication hole being in communication with the via and a receiver receiving the piezoelectric actuator; and stacking and bonding the package part onto the intermediate layer.

The bonding of the intermediate layer and the package part may be performed by using anodic bonding or glass frit bonding, polymer bonding, low-temperature silicon direct bonding using plasma, or eutectic bonding.

The processing of the intermediate layer may be performed by a sand blast or etching process.

The processing of the intermediate layer may include: forming the receiver to have a depth equal to a value acquired by adding the thickness of the piezoelectric actuator to a processing error towards the top of the bottom of the intermediate layer; and forming the communication hole connecting a part of the top of the receiver with the via.

The method may further include: forming an oxide film on the top and bottom of the package part and the side of the via; and removing an oxide film from the bottom of the package part.

The removing of the oxide film may be performed by using a chemical mechanical planarization (CMP) process.

The forming of the electrical connector may fill the via with metal by using electroplating.

In addition, the method may further include forming a connection member electrically connecting the piezoelectric actuator with the electrical connector.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cutaway perspective view illustrating an inkjet head assembly according to an exemplary embodiment of the present invention;

FIG. 2 is a schematic cross-sectional view illustrating an inkjet head assembly according to an exemplary embodiment of the present invention;

FIG. 3 is an enlarged cross-sectional view of part A of FIG. 2;

FIG. 4 is a schematic plan view illustrating an ink path of a package part of an inkjet head assembly according to an exemplary embodiment of the present invention;

FIG. 5 is a cross-sectional view of an ink path of an inkjet head assembly according to an exemplary embodiment of the present invention;

FIG. 6 is a schematic perspective view illustrating a mounting structure of an inkjet head assembly according to an exemplary embodiment of the present invention;

FIG. 7 is a schematic cross-sectional view illustrating a mounting structure of an inkjet head assembly according to an exemplary embodiment of the present invention;

FIG. 8 is a schematic cross-sectional view illustrating an inkjet head assembly according to another embodiment of the present invention;

FIGS. 9A to 91 are a process diagram illustrating a method for manufacturing an inkjet head assembly according to an exemplary embodiment of the present invention; and

FIGS. 10A to 10C are a process diagram illustrating a method for manufacturing an inkjet head assembly according to another embodiment of the present invention.

### DETAILED DESCRIPTION OF THE PREFERRED EMBODIMENT

Exemplary embodiments of the present invention will now be described in detail with reference to the accompanying drawings. However, it should be noted that the spirit of the present invention is not limited to the embodiments set forth herein and those skilled in the art and understanding the present invention can easily accomplish retrogressive inventions or other embodiments included in the spirit of the present invention by the addition, modification, and removal of components within the same spirit, and those are to be construed as being included in the spirit of the present invention.

Further, throughout the drawings, the same or similar reference numerals will be used to designate the same components or like components having the same functions in the scope of the similar idea.

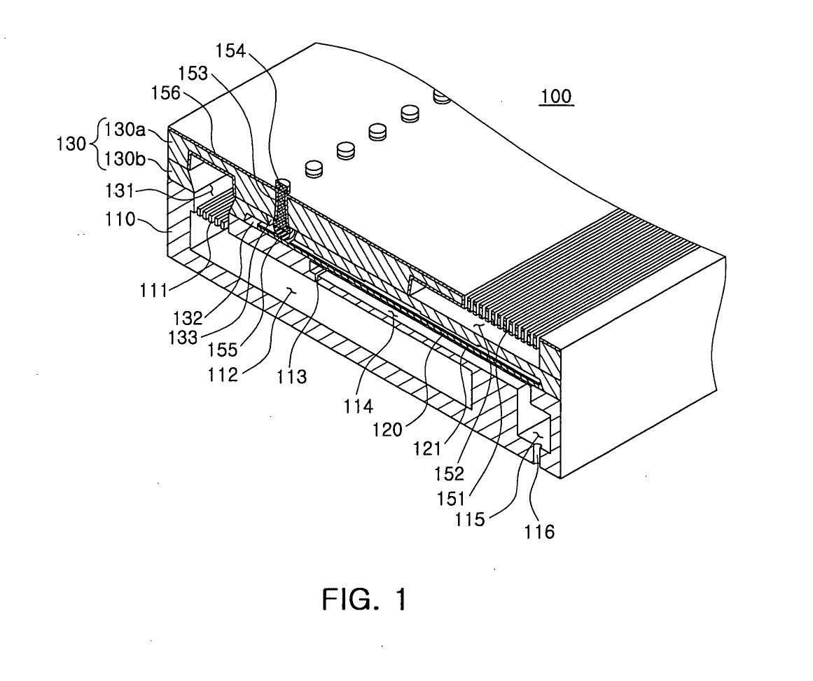

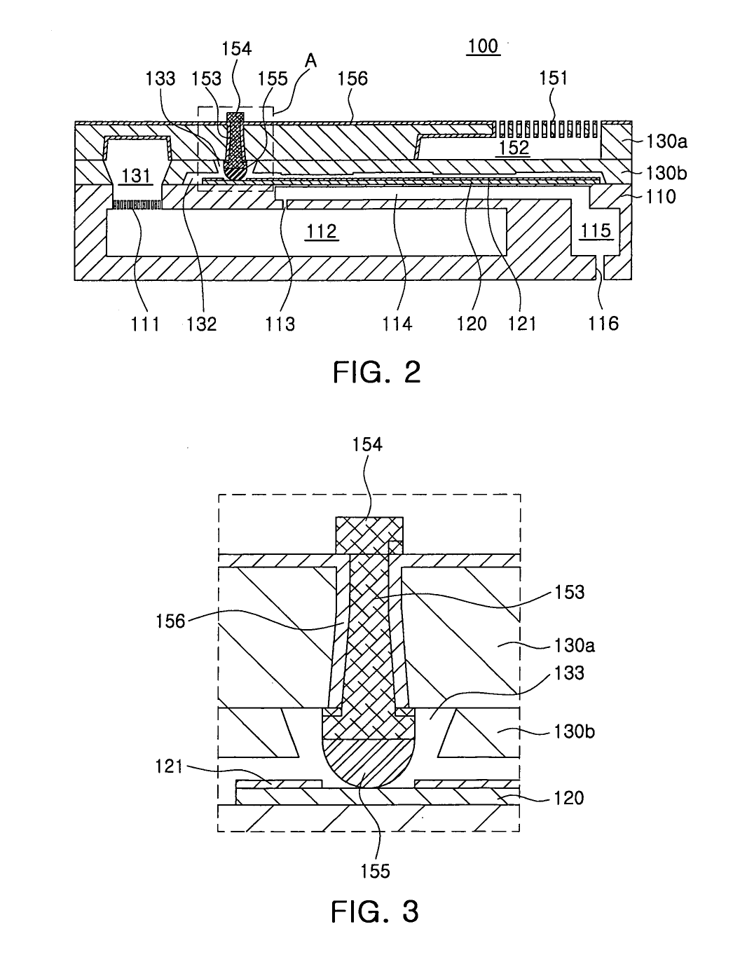

FIG. 1 is a schematic cutaway perspective view illustrating an inkjet head assembly according to an exemplary embodiment of the present invention, FIG. 2 is a schematic cross-sectional view illustrating an inkjet head assembly according to an exemplary embodiment of the present invention, and FIG. 3 is an enlarged cross-sectional view of part A of FIG. 2.

Referring to FIGS. 1 to 3, the inkjet head assembly 100 according to the exemplary embodiment of the present invention includes an inkjet head plate with an inkjet path, a piezoelectric actuator 120 providing driving force for ejecting ink to the inkjet head plate 110, and a package part 130 for electrical wires applying voltage to the piezoelectric actuator 120.

The inkjet head plate 110 may include an ink inlet 111 through which ink is introduced, a reservoir 112 storing the ink introduced through the ink inlet 111, a plurality of pressure chambers 114 provided in a lower part of a position in which the piezoelectric actuator 120 is mounted, and a plurality of nozzles 116 ejecting ink. A plurality of restrictors 113 may be formed between the reservoir 112 and the pressure chamber 114 in order to restrict the backflow of ink of the pressure chamber 114 when ink is ejected. Further, the pressure chambers 114 and the nozzles 116 may be connected with each other by a plurality of dampers 115.

The inkjet head plate 110 may be appropriately formed by components constituting the ink path on an upper substrate and a lower substrate and bonding the upper substrate and the lower substrate to each other by a process such as silicon direct bonding (SDB). At this time, the upper substrate may be a single crystal silicon substrate or an SOI substrate, and the lower substrate may be formed by the SOI substrate. Further, the inkjet head plate 110 is not limited thereto, but the ink path may be constituted by more substrates and in some cases, the ink path may be implemented by one substrate. The components constituting the ink path are merely exemplary, and the ink path may have various configurations depending on requirements or design specifications.

The piezoelectric actuator 120 is disposed on the top of the inkjet head plate 110 to face the pressure chamber 114 of the inkjet head plate 110 and provides the driving force for ejecting ink introduced into the pressure chamber 114 to the nozzle 116. For example, the piezoelectric actuator 120 may include a lower electrode serving as a common electrode, a piezoelectric film deformed by applying voltage, and an upper electrode serving as a driving electrode.

The lower electrode may be formed on the overall surface of the inkjet head plate 110, and may be made of one conductive metallic material, but is preferably constituted by two metal thin-film layers made of titanium (Ti) and platinum (Pt). The lower electrode serves as a diffusion prevention layer preventing the interdiffusion between the piezoelectric film and the inkjet head plate 110 as well as the common electrode. The piezoelectric film is formed above the lower electrode and disposed on the tops of the plurality of pressure chambers 114. The piezoelectric film may be made of a piezoelectric material, preferably, a lead zirconate titanate (PZT) ceramic material. The upper electrode is formed above the piezoelectric film and may be made of any one of materials such as Pt, Au, Ag, Ni, Ti, and Cu.

In the embodiment, a configuration in which ink is ejected by a piezoelectric driving mechanism using the piezoelectric actuator 120 is described as an example, but the present invention is not restricted or limited by the ink ejection mechanism and may be configured to eject ink in various mechanisms such as a thermal driving mechanism, and the like, depending on the requirements.

The package part 130 may include a path forming layer 130a where the ink path for moving ink provided from the ink storage tank to the ink inlet 111 of the inkjet head plate 110 is formed and an intermediate layer 130b for bonding the package part 130 and the inkjet head plate 110 to each other. The package part 130 may be formed by a silicon wafer and at this time, the path forming layer 130a may be formed by a single crystal silicon wafer and the intermediate layer 130b may be formed by a glass wafer. The path forming layer 130a and the intermediate layer 130b may be bonded to each other by anodic bonding or glass frit bonding.

The configuration of the package part 130 according to the embodiment of the present invention is merely exemplary and the package part 130 may be formed by a single silicon wafer, a silicon wafer constituted by a plurality of layers, or an SOI wafer. The design of the package part 130 may be variously modified depending on the requirements. The configurations of the path forming layer 130a and the intermediate layer 130b are also exemplary. The intermediate layer 130b is formed by the silicon wafer so as to bond the path forming layer 130a and the intermediate layer 130b to each other by silicon direct bonding. Besides, the design may be variously modified by polymer bonding, low-temperature silicon direct bonding using plasma, or eutectic bonding.

The path forming layer 130a may include an ink inlet 151 through which ink provided from the ink storage tank is introduced, an ink transfer part 152 serving as a path for moving ink to the inkjet head plate 110, and a via 153 for electrical wires applying voltage to the piezoelectric actuator 120. The via 153 penetrates upper and lower parts of the path forming layer 130a and may be disposed at one upper side of the piezoelectric actuator 120. At this time, the ink inlet 151 may be formed at an opposite side to the via 153. Therefore, in a mounting structure of the inkjet head assembly, the ink storage tank is disposed at the center of an array of the inkjet head assembly and the electrical wires may be connected to a side surface of the inkjet head assembly, thereby reducing a mounting dimension of the inkjet head assembly.

The ink inlet 151, the ink transfer part 152, and the via 153 are formed on the silicon wafer through an etching process. In particular, the via 153 may be formed in a shape of a vertical hole having a constant diameter by dry etching, or, the side of the via 153 having a diameter gradually increasing toward the lower part of the path forming layer 130a may be inclined. The via 153 may be formed by reactive-ion etching (RIE), in particular, deep reactive-ion etching (DRIE) among various types of dry etching processes. An electrical connector 154 is formed by filling the via 153 with a metal for electrical wires.

The electrical connector 154 may be formed by plating the via 153 with a metal through electroplating and the metal used therein may be any one of Pt, Au, Ag, Ni, Ti, and Cu. The electrical connector 154 may have an I-beam shaped cross-section in which the top and the bottom of the electrical connector 154 are larger than the circumference of the via 153 in order to ensure an electrical connection. The cross-section of the electrical connector 154 is not limited thereto and besides, the corresponding shape may have shapes such as a 1 shape, a T shape, or the like. Further, the side of the electrical connector 154 may be formed vertically or obliquely so as to correspond to the shape of the via 153.

The electrical connector 154 may include a connection member 155 on the lower end thereof in order to connect with the piezoelectric actuator 120. The connection member 155 is made of a conductive medium having a bonding force of a level such that an electrical short-circuit may be avoided and for example, the connection member 155 may be formed by a projection type connection member such as a solder ball or a solder bump, and an anisotropic conductive film (ACF) and various load applied conductive media may be used. In the embodiment, the solder ball is used as the connection member 155.

In order to prevent an overflow of solder at the reflow of solder for bonding the solder ball 155 to the piezoelectric actuator 120, a polymer film 121 may be applied to the top of the piezoelectric actuator 120. At this time, the polymer film 121 is formed on the top of the piezoelectric actuator 120 other than the bonding portion of the solder. This may be formed by developing materials such as a photosensitive polymer (photoresist), etc.

In the path forming layer 130a, an oxide film 156 may be formed on the top, a portion where the via 153 is formed, and a portion where the ink transfer part 152 is formed. The oxide film 156 serves to prevent impurities contained in a silicon crystal of the path forming layer 130a which is formed by the silicon wafer from being diffused. The oxide film 156 may be formed by oxidizing silicon of the path forming layer 130a and film-forming the oxidized silicon on the surface of the path forming layer 130a and thereafter, removing an oxide film formed on the lower surface of the path forming layer 130a by chemical-mechanical processing.

The intermediate layer 130b may include a passage 131 through which ink of the ink transfer part 152 of the path forming layer 130a is supplied to the ink inlet of the inkjet head plate 110, a receiver 132 receiving an upper part of the piezoelectric actuator 120, and a communication hole 133 connecting the receiver 132 and the via 153 with each other. The receiver 132 of the piezoelectric actuator 120 is formed by a groove concaved towards the bottom from the top of the intermediate layer 130b. The receiver 132 may have a shape corresponding to the shape of the piezoelectric actuator 120 and have a depth equal to a value acquired by adding the thickness of the piezoelectric actuator to a processing error. The receiver 132 and the communication hole 133 may be performed by performing a sand blasting or etching process onto a glass wafer.

The package part 130 formed by the anodic bonding of the path forming layer 130a and the intermediate layer 130b are stacked and bonded onto the top of the inkjet head plate 110. Specifically, the bottom of the intermediate layer 130b and the top of the inkjet head plate 110 are bonded to each other by anodic bonding or glass frit bonding. At this time, the connection member 155 of the electrical connector 154 is bonded to the top of the piezoelectric actuator 120. In the embodiment, a bonding unit at the edge supports bonding of the inkjet head plate 110 and the package part 130.

As such, in the inkjet head assembly 100 according to the embodiment, since the inkjet head plate 110 and the package part 130 may be bonded to each other at a wafer level, productivity is improved through an increase in processing yield and a saving in manufacturing costs.

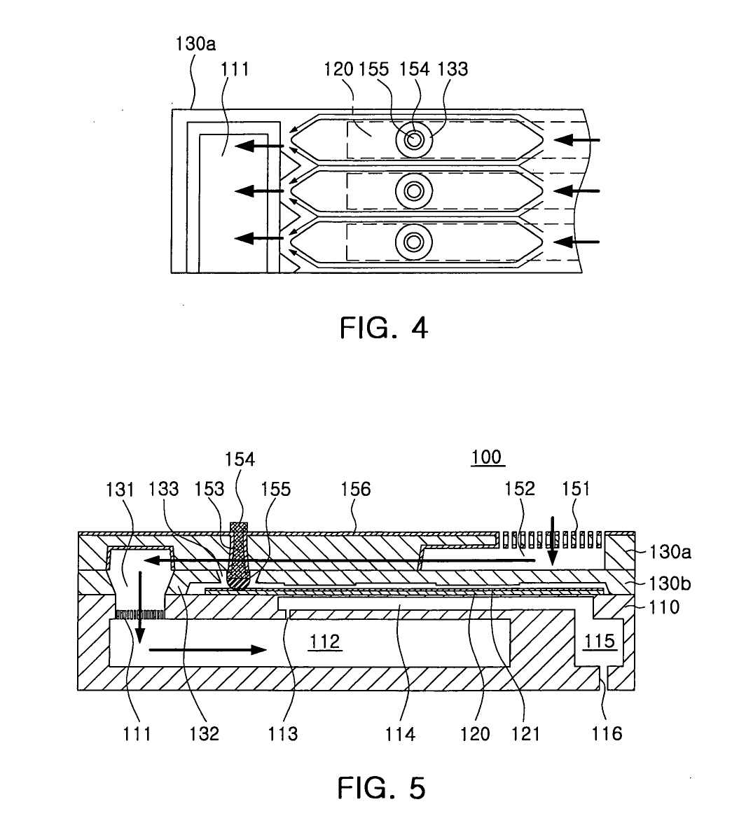

FIGS. 4 and 5 are a schematic plan view and a cross-sectional view of an ink path of a package part of an inkjet head assembly according to an exemplary embodiment of the present invention, respectively.

Referring to FIGS. 4 and 5, ink introduced into the ink inlet 151 from an ink storage tank (not shown) is transferred through the ink transfer part 152 in the direction indicated by arrows. At this time, ink moving between the walls in which the via 153 for filling the electrical connector 154 is formed moves to the ink inlet 111 of the inkjet head plate 110 from the end of the ink transfer part 152 through the passage 131 of the intermediate layer 130b.

A movement path of the ink introduced to the inkjet head plate 110 through the ink inlet 111 is not shown, but is substantially the same as an ink movement path in a known inkjet head. That is, the ink introduced to the ink inlet 111 moves to the pressure chamber 114 from the reservoir 112 through the plurality of restrictors 113 and the ink in the pressure chamber 114 is subsequently ejected from the nozzle 116 to the outside through the plurality of dampers 115 by driving the piezoelectric actuator 120.

Hereinafter, an operation of the inkjet head assembly 100 will be described. The ink supplied from the ink storage tank (not shown) through the ink inlet 151 moves in the direction indicated by arrows of FIGS. 4 and 5 to be supplied to the inside of each of the plurality of pressure chambers 114 of the inkjet head plate 110. When voltage is applied to the piezoelectric actuator 120 through the electrical connector 154 connected with a flexible printed circuit board (FPCB) (not shown) while the pressure chamber 114 is filled with ink, a piezoelectric film is deformed and as a result, the top of the inkjet head plate 110 serving as a vibration plate is bent downward. The volume of the pressure chamber 114 is reduced by bending of the top of the inkjet head plate 110 and the ink in the pressure chamber 114 is ejected to the outside through the nozzle 116 by the resulting rise in the pressure in the pressure chamber 114.

Subsequently, when the voltage being applied to the piezoelectric actuator 120 is interrupted, the piezoelectric film is restored and as a result, the volume of the pressure chamber 114 is increased while the top of the inkjet head plate 110 serving as the vibration plate restored. The ink is introduced to the inside of the pressure chamber 114 from the reservoir 112 by the resulting reduction of the pressure in the pressure chamber 114 and surface tension by a meniscus of the ink formed in the nozzle 116.

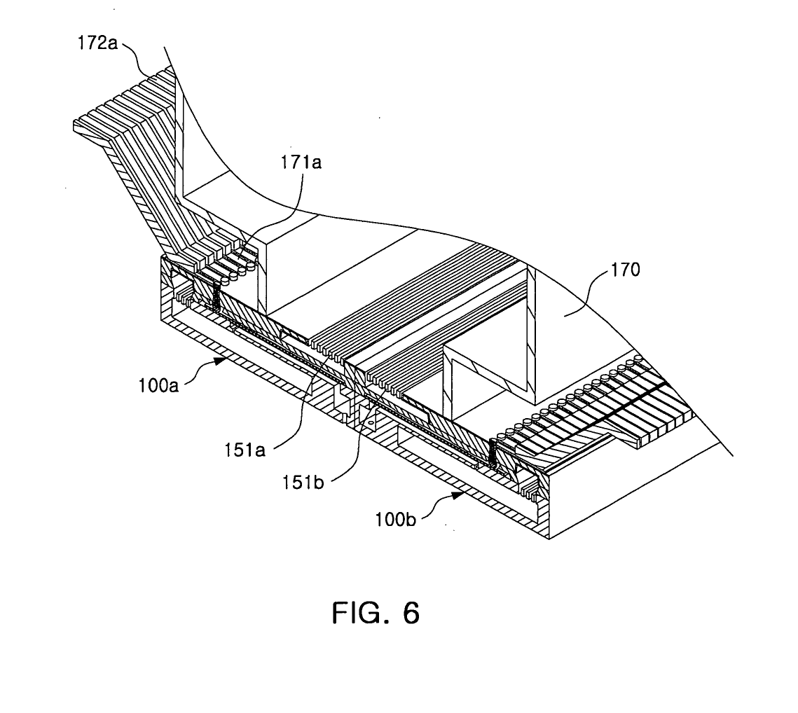

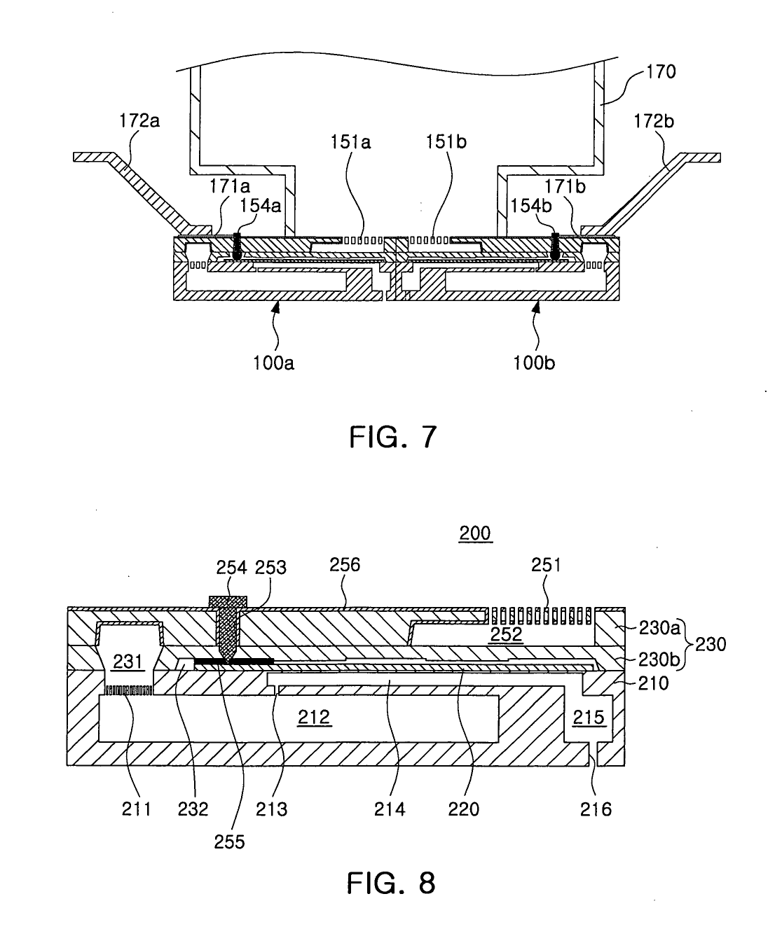

FIGS. 6 and 7 are a schematic perspective view and a cross-sectional view illustrating a mounting structure of an inkjet head assembly according to an exemplary embodiment of the present invention, respectively.

Referring to FIGS. 6 and 7, the mounting structure of the inkjet head assembly includes a first inkjet head assembly 100a and a second inkjet head assembly 100b that are arranged symmetrically with relation to each other, an ink storage tank disposed at the center of the top of the first and second inkjet head assemblies 100a and 100b, bonding portions 171a and 171b formed on the tops of the first and second inkjet head assemblies 100a and 100b and connected to the electrical connectors 154a and 154b, respectively, and FPCBs 172a and 172b connected to the bonding portions 171a and 171b for applying voltage of the piezoelectric actuator of the first and second inkjet head assemblies 100a and 100b. The bonding portions 171a and 171b may be made of an epoxy resin. In particular, the bonding portions 171a and 171b may be formed by the anisotropic conductive film (ACF).

As such, the inkjet head assembly according to the exemplary embodiment of the present invention connects the electrical wires for applying the voltage to the piezoelectric actuator 120 through the electrical connector 154 which is substantially vertical to the surface of the inkjet head assembly to thereby markedly reduce the dimension of the inkjet head assembly required to bond the known FPCB. Accordingly, the overall width of the inkjet head assembly according to the embodiment is reduced from the overall width of the known inkjet head assembly by a dimension for bonding the FBCB and a dimension for bonding the ACF. At this time, since the ink storage tank is disposed at the center of the top of a set of inkjet head assemblies having a symmetrical structure, in which the nozzles are alternately formed, the mounting dimension of the inkjet head assembly is markedly reduced.

Since the reduction of the mounting dimension of the inkjet head assembly markedly reduces the overall width of the inkjet head assembly formed by the wafer-level package, it is possible to manufacture more inkjet head assemblies per wafer.

Accordingly, productivity is improved through the increase in processing yield and a saving of manufacturing costs.

FIG. 8 is a schematic cross-sectional view illustrating an inkjet head assembly according to another embodiment of the present invention.

In the inkjet head assembly according to another embodiment of the present invention shown in FIG. 8, a connection member of metal for electrical wires is formed by an anisotropic conductive film (ACF). Since other components of the inkjet head assembly according to another embodiment of the present invention are the same as those of the inkjet head assembly according to the exemplary embodiment of the present invention shown in FIGS. 1 to 3, the components will not described in detail and hereinafter, differences will be principally described.

Referring to FIG. 8, the inkjet head assembly 200 according to another embodiment of the present invention also includes an inkjet head plate 210, a piezoelectric actuator 220, and a package part 230. The inkjet head plate 210 includes an ink inlet 211, a reservoir 212, a plurality of restrictors 213, a plurality of pressure chambers 214, a plurality of dampers 215, and a plurality of nozzles 216 that are formed on an ink path.

The package part 230 includes a path forming layer 230a including an ink inlet 251, an ink transfer part 252, and a via 253, and an intermediate layer 230b including a connection passage 231 of the ink transfer part 252 and the ink inlet 211 and a receiver 232 receiving the piezoelectric actuator 220, and an electrical connector 254 formed by filling the via 253 with a metal for electrical wires. The via 253 may be formed in a shape of a vertical hole having a constant diameter by dry etching or in a shape of an inclined hole having a diameter gradually increasing toward a lower part of the path forming layer 230a.

The electrical connector 254 may be formed by plating any one metal of metals such as Pt, Au, Ag, Ni, Ti, and Cu through electroplating of the via 253. A cross-section of the electrical connector 254 may have various shapes such as an I-beam shape, a 1 shape, a T shape, or the like.

The ACF 255 as a load applied conductive medium is applied to a portion on the top of the piezoelectric actuator 220 connected with the electrical connector 254. In the embodiment, the ACF 255 is used as the conductive medium, but is not limited thereto and besides, a curable adhesive having electrical conductivity may be used as the conductive medium.

In the inkjet head assembly according to the exemplary embodiment of the present invention, a solder ball 155 is used as the conductive medium. The solder ball 155 is limitative in temperature when the solder ball 155 is bonded with the piezoelectric actuator 120, but since the ACF 255 of the embodiment is a heat-resistant load applied conductive medium, the ACF 255 can overcome the limit of the solder ball 155. Further, in the embodiment, a polymer film for preventing the overflow of solder at the time of the reflow of the solder does not need to be formed on the top of the piezoelectric actuator 220.

The path forming layer 230a and the intermediate layer 230b are bonded to each other by anodic bonding or glass frit bonding. The package part 230 and the inkjet head plate 210 that are formed as above may be bonded to each other at a wafer level by the anodic bonding, or the like. Bonding portions of the inkjet head assembly 200 are the bottom of the intermediate layer 230b and the top of the inkjet head plate 210. The bonding portions are supported by the bonding of the outer part of the inkjet head assembly 200. In this case, the electrical connector 254 and the piezoelectric actuator 220 are connected by the ACF 255.

Hereinafter, a method for manufacturing an inkjet head assembly having the above configuration according to the embodiment of the present invention will be described.

First, a preferred manufacturing method of the present invention will be schematically described. A package part and an inkjet head plate are each manufactured by forming an ink path on a wafer and the package part is stacked and bonded onto the inkjet head plate, thereby completing the inkjet head assembly according to the embodiment of the present invention. Meanwhile, steps of manufacturing the package part and the inkjet head plate may be performed regardless of the order.

That is, any one of the package part and the inkjet head plate may first be manufactured and the package part and the inkjet head plate may be manufactured at the same time. Further, the steps of manufacturing the inkjet head plate are steps of generally forming the ink path on one or more wafers. Hereinafter, for convenience of description, the steps of manufacturing the inkjet head plate will not be described in detail.

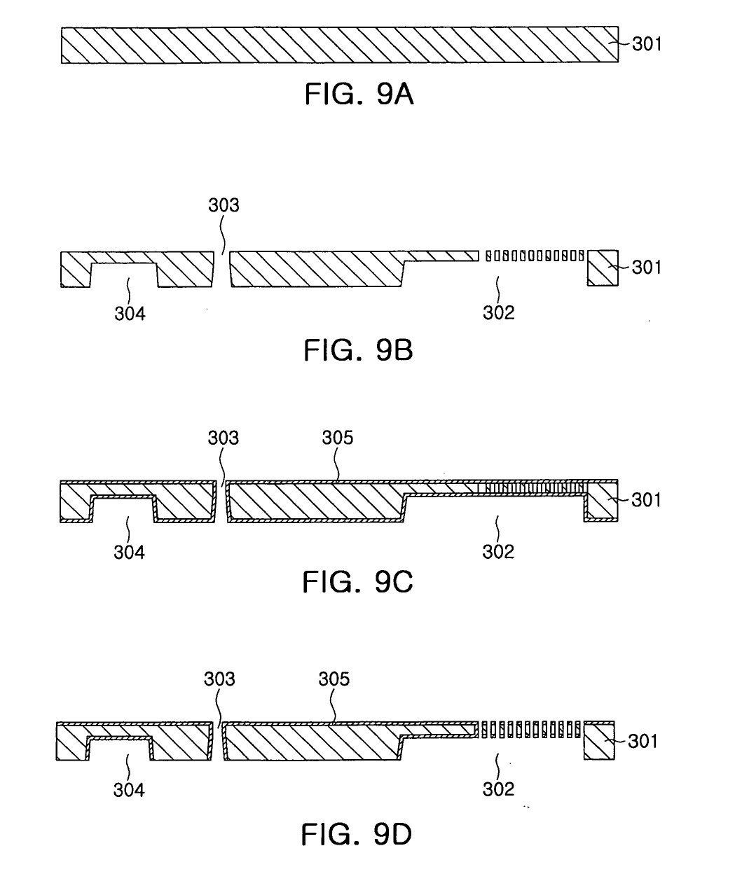

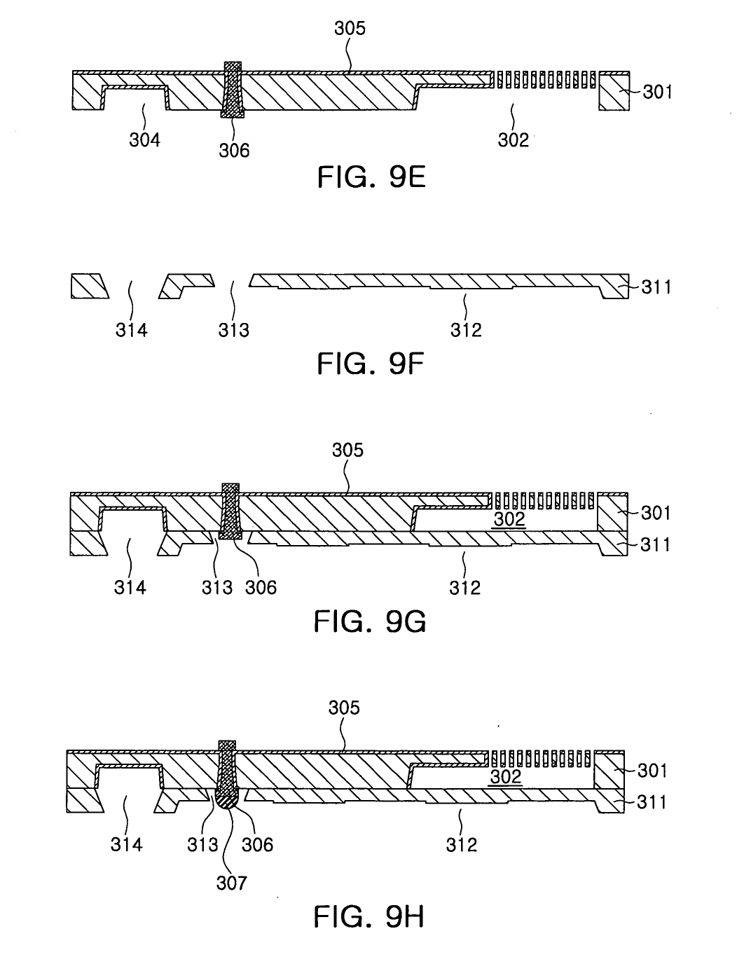

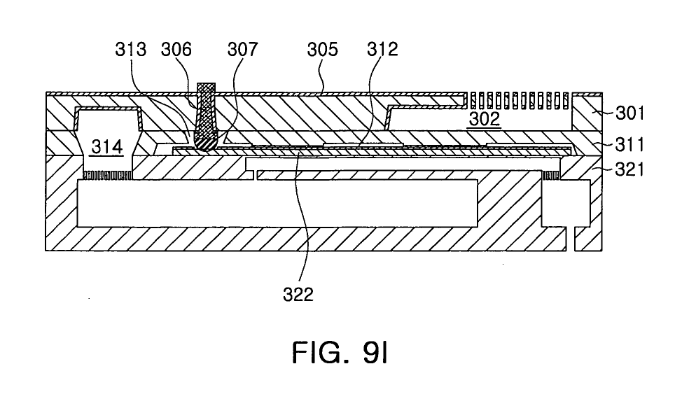

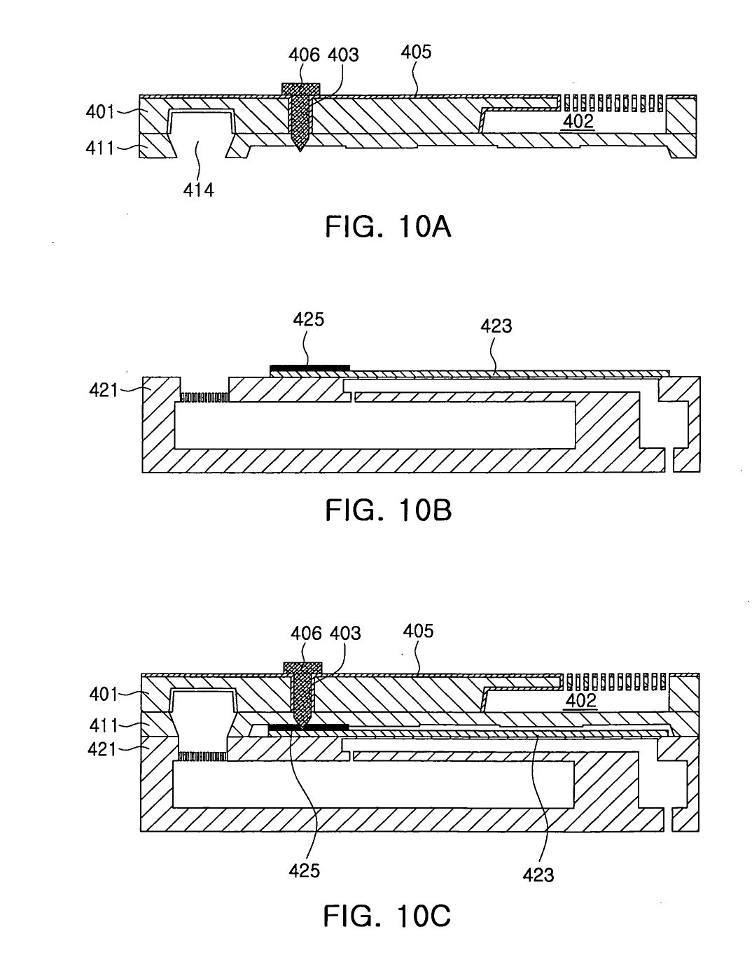

FIGS. 9A to 9I are process diagrams illustrating a method for manufacturing an inkjet head assembly according to an exemplary embodiment of the present invention.

FIGS. 9A to 9F are diagrams for describing steps of manufacturing a package part of an inkjet heat assembly according to the exemplary embodiment of the present invention. Steps of manufacturing a path forming layer and an intermediate layer of the package part may be performed regardless of the order in which they are performed. However, for convenience of description, in the order of the path forming layer and the intermediate layer, each manufacturing method will be described.

First, as shown in FIG. 9A, a silicon wafer 301 is provided as the path forming a layer. As the silicon wafer 301, a single crystal silicon substrate or an SOI wafer may be used.

Next, as shown in FIG. 9B, an ink inlet 302, a via 303, and an ink transfer part 304 are formed on the silicon wafer 301 through an etching process. Specifically, a photoresist is applied to the bottom of the silicon wafer 301 and an opening for forming the ink inlet 302, the via 303, and the ink transfer part 304 is formed by patterning the applied photoresist. At this time, the photoresist may be patterned by a known photolithography process including exposure and development.

The silicon wafer 301 exposed through the opening is etched by using the patterned photoresist as an etching mask so as to form the ink inlet 302, the via 303, and the ink transfer part 304. At this time, as etching, a dry etching method such as deep reactive-ion etching (DRIE) is preferably used, but as a silicon etching solution, for example, the etching may be performed by a wet etching method using tetramethylammonium hydroxide (TMAH) or potassium hydroxide (KOH). The via 303 is etched to penetrate the top and the bottom of the silicon wafer 301. The via 303 may be a vertical hole having a constant diameter or an inclined hole having a diameter gradually increasing toward a lower part of the silicon wafer 301. Next, when the photoresist is removed, the ink inlet 302, the via 303, and the ink transfer part 304 are formed on the silicon wafer 301.

Next, as shown in FIG. 9C, by wet and/or dry-oxidizing the silicon wafer 301 in the area in which the ink inlet 302, the via 303, and the ink transfer part 304 are formed, a silicon oxide film 305 is formed on the top and the bottom of the silicon wafer 301 and portions where the ink let 302, the via 303, and the ink transfer part 304 are formed. At this time, the silicon oxide film 305 has a thickness of approximately 5,000 to 15,000 A.

Next, as shown in FIG. 9D, the path forming layer 130a which is an upper layer of the package part 130 of the inkjet head assembly shown in FIG. 1 is formed by removing the silicon oxide film formed on the bottom of the silicon wafer 301. At this time, the silicon oxide film on the bottom of the silicon wafer 301 may be removed by a chemical mechanical planarization (CMP) method.

Next, as shown in FIG. 9E, the electrical connector 306 is formed in the via 303 where the silicon oxide film is formed. Specifically, the electrical connector 306 is formed by plating metal made of any one of metals such as Pt, Au, Ag, Ni, Ti, and Cu to the via 303 by an electroplating process. At this time, a cross-section of the electrical connector 306 may have a 1 shape, a T shape, an I-beam shape, or the like.

FIG. 9F is a diagram illustrating a step of forming the intermediate layer 130b by a lower layer of the package part 130 of the inkjet head assembly 100 according to the exemplary embodiment of the present invention.

As shown in FIG. 9F, a piezoelectric actuator receiver 312, a communication hole 313 which is in communication with the via, and a passage 314 supplying ink to the ink inlet of the inkjet head plate are formed by preparing a glass wafer 311 for forming the intermediate layer 130b and by sand-blasting or etching the glass wafer 311. In the embodiment, the glass wafer is used as the intermediate layer, but is not limited thereto and various wafers may be used as the intermediate layer depending on requirements.

A method of forming the receiver 312, the communication hole 313, and the passage 314 by etching the glass wafer 311 may be performed in the same manner as the etching process of the silicon wafer 301. That is, after a material having higher selectivity than glass, i.e., the photoresist is applied onto the bottom of the glass wafer 311 and patterned, the receiver 312, the communication hole 313, and the passage 314 are formed by etching the glass wafer 311 by using the patterned photoresist as the etching mask and the photoresist is removed. At this time, the etching may be the dry etching process such as the DRIE process or the wet etching process using the etching solution.

At this time, the receiver 312 has a shape of a groove concaved towards the top from the bottom of the glass wafer 311 so as to receive the piezoelectric actuator. The receiver 312 may have a shape corresponding to the shape of the piezoelectric actuator and have a depth equal to a value acquired by adding the thickness of the piezoelectric actuator to a processing error. The communication hole 313 penetrates the top of the receiver 312 and the top of the glass wafer 311. The passage 314 penetrates the top and the bottom of the glass wafer 311.

Next, as shown in FIG. 9G, the package part 130 of the inkjet head assembly according to the exemplary embodiment of the present invention shown in FIG. 1 is formed by bonding the silicon wafer 301 and the glass wafer 311 to each other. At this time, the silicon wafer 301 and the glass wafer 311 may be bonded to each other by anodic bonding or glass frit bonding.

Next, as shown in FIG. 9H, a solder ball 307 as a connection member for bonding the electrical connector 306 of the package part 306 to an electrode of the piezoelectric actuator is formed on the lower end of the electrical connector 306. The solder ball 307 may be made of an alloy of tin (Sn), lead (Pb), copper (Cu), or silver (Ag). A lead free solder ball not including the lead (Pb) may be used. The solder ball forming process may be performed by using a known process, for example, the solder ball 307 may be formed by dotting flux onto a solder ball attachment portion and thereafter, fusing the solder ball.

In the embodiment, forming the electrical connector 306 in the via 303 of the silicon wafer 301, bonding the silicon wafer 301 and the glass wafer 311 to each other, and forming the solder ball 307 on the lower end of the electrical connector 306 are performed in sequence, but the processes do not need to be performed in accordance with the order. For example, after the silicon wafer 301 and the glass wafer 311 are first bonded to each other, the electrical connector is formed in the via 303 and the solder ball 307 may be formed. Further, after the electrical connector 306 and the solder ball 307 are formed in the via 303, the silicon wafer 301 and the glass wafer 311 may be bonded to each other. As such, the processes may be appropriately selected and performed by those skilled in the art depending on a process environment or requirements.

Next, as shown in FIG. 9I, the inkjet head assembly is completed by stacking and bonding the package part onto the inkjet head plate 321. Specifically, the bottom of the glass wafer 311 and the top of the inkjet head plate 321 which are the intermediate layers of the package part are bonded to each other by the anodic bonding. At this time, the electrode of the piezoelectric actuator 322 is connected with the electrical connector 306 through a reflow process of the solder ball 307. In order to prevent the overflow of solder at the time of the reflow of the solder ball 307, a polymer film such as the photoresist may be applied to the top of the piezoelectric actuator 322 at the time of manufacturing the inkjet head plate 321.

In the embodiment, the solder ball 307 as the connection member for bonding the electrical connector 306 to the electrode of the piezoelectric actuator is used, but the present invention is not limited thereto and besides, a curable adhesive having electrical conductivity may be used as the connection member.

FIGS. 10A to 10C are process diagrams illustrating a method for manufacturing an inkjet head assembly according to another embodiment of the present invention. Hereinafter, the method for manufacturing an inkjet head assembly according to another embodiment of the present invention will be described with reference to FIGS. 10A to 10C.

The inkjet head assembly according to the embodiment is different from the inkjet head assembly according to the exemplary embodiment of the present invention shown in FIG. 1 in that an ACF which is a heat-resistant load applied conductive medium as a connection member is used. Therefore, differences will now be principally described.

Referring to FIG. 10A, a package part is formed by bonding a silicon wafer 401 where a via 403 filled with an electrical connector 406 and a glass wafer 411 where a piezoelectric actuator receiver 412 are formed to each other. The process of forming the package part shown in FIG. 10 of the embodiment is substantially the same as the process of forming the package part by forming the via on the silicon wafer, forming the electrical connector in the via, and bonding the silicon wafer and the glass wafer to each other, that is, the processes shown in FIGS. 9A to 9G among the processes according to the exemplary embodiment of the present invention shown in FIGS. 9A to 9I. Therefore, the processes of forming the package part will not be described in detail.

Referring to FIG. 10B, the load applied conductive medium as a connection member is applied to a connection portion between the piezoelectric actuator 423 and the electrical connector 406 on the top of the piezoelectric actuator 423. For example, the ACF 425 may be applied. The ACF 425 as a heat-resistant load applied conductive medium may overcome a problem that the solder ball 155 has the limit of temperature when the solder ball 155 is bonded with the piezoelectric actuator 120 in the exemplary embodiment of the present invention. According to the embodiment, the process of applying the photoresist onto the top of the piezoelectric actuator in order to prevent the overflow of the solder is omitted.

Next, the inkjet head assembly is completed by stacking and bonding the package part onto the top of the inkjet head plate 421 applied with the ACF 425. Specifically, the bottom of the glass wafer 411 and the top of the inkjet head plate 421 which are intermediate layers of the package part are bonded to each other by anodic bonding and the electrical connector 406 is connected with an electrode of the piezoelectric actuator 423 through the ACF 425. At this time, bonding of the inkjet head plate and the package part is supported by bonding portions of the edges. As such, in the inkjet head assembly according to the present invention, the inkjet head plate and the package part may be bonded to each other in the wafer level.

Although not shown, hereinafter, the mounting method of the inkjet heat assembly according to the embodiment of the present invention will be described with reference to the mounting structure of the inkjet head assembly according to the exemplary embodiment of the present invention shown in FIGS. 6 and 7.

As shown in FIGS. 6 and 7, the inkjet head assemblies according to the present invention are generally symmetrical to each other. Bonding portions 171a and 171b for electrically connecting electrical connectors 154a and 154b and FPCBs 172a and 172b to each other are formed at side surface parts of the tops of a first inkjet head assembly 100a and a second inkjet head assembly 100b. The bonding portions 171a and 171b may be formed by a curable adhesive having electrical conductivity and, for example, an ACF or epoxy resin may be used.

Next, the FPCBs 172a and 172b and the electrical connectors 154a and 154b are connected to each other through the bonding portions 171a and 171b.

Ink storage tanks 170 are installed at the centers of the tops of the first inkjet head assembly 100a and the second inkjet head assembly 100b. Installing the ink storage tanks 170, forming the bonding portions 171a and 171b in the inkjet head assemblies 100a and 100b, and connecting the FPCBs 172a and 172b are performed regardless of the order. Therefore, the ink storage tanks 170 are first installed and thereafter, the bonding portions 171a and 171b may be formed in the inkjet head assemblies 100a and 100b and the FPCBs 172a and 172b may be connected.

As set forth above, according to exemplary embodiments of the present invention, it is possible to manufacture an inkjet head assembly in a wafer level package by simplifying a connection structure of an electrical wire and ink storage tank.

Further, since an overall width of an inkjet head is reduced, the number of manufacturable inkjet heads in one wafer is increased and as a result, productivity is improved through an increase in processing yield and a saving of manufacturing costs.

Furthermore, in the inkjet head assembly according to the present invention, since a mounting dimension of the inkjet head is reduced, it is possible to configure the inkjet head in an array mechanism.

While the present invention has been shown and described in connection with the exemplary embodiments, it will be apparent to those skilled in the art that modifications and variations can be made without departing from the spirit and scope of the invention as defined by the appended claims.

What is claimed is:

1. An inkjet head assembly, comprising:
an inkjet head plate including an ink path;
a piezoelectric actuator facing a pressure chamber in the inkjet head plate and providing driving force for ejecting ink to a nozzle from the pressure chamber;
a package part stacked on the inkjet head plate and including a path moving ink introduced from the outside to an inlet of the inkjet head plate; and
an electrical connector filling a via penetrating the package part and electrically connected with the piezoelectric actuator.

2. The inkjet head assembly of claim 1, further comprising a connection member electrically connecting the piezoelectric actuator with the electrical connector.

3. The inkjet head assembly of claim 2, wherein the connection member is formed by a solder ball.

4. The inkjet head assembly of claim 3, further comprising a polymer film provided on the piezoelectric actuator and preventing the overflow of the solder ball.

5. The inkjet head assembly of claim 4, wherein the polymer film is a photosensitive polymer (photoresist).

6. The inkjet head assembly of claim 2, wherein the connection member is an anisotropic conductive film (ACF) or a solder bump.

7. The inkjet head assembly of claim 1, wherein the via has a shape of a vertical hole having a predetermine diameter or a shape of an inclined hole having a diameter gradually increasing towards the bottom from the top of the package part.

8. The inkjet head assembly of claim 1, wherein the via is a through-hole formed by deep reaction-ion etching (DRIE).

9. The inkjet head assembly of claim 1, wherein the package part is formed by a single crystal silicon wafer or an SOI wafer.

10. The inkjet head assembly of claim 1, further comprising an intermediate layer bonding the package part and the inkjet head plate to each other.

11. The inkjet head assembly of claim 10′, wherein the intermediate layer is formed by a glass wafer or a silicon wafer.

12. The inkjet head assembly of claim 10, wherein the intermediate layer includes:
a receiver receiving the top of the piezoelectric actuator; and
a communication hole being in communication with the receiver and the via.

13. The inkjet head assembly of claim 12, wherein the receiver is a groove concaved towards the top from the bottom of the intermediate layer, and has a shape corresponding to the shape of the piezoelectric actuator and has a depth equal to a value acquired by adding the thickness of the piezoelectric actuator to a processing error.

14. The inkjet head assembly of claim 1, further comprising a conductive film formed on the package part and connecting the electrical connector with an external power supply applying voltage to the piezoelectric actuator.

15. The inkjet head assembly of claim 1, wherein a cross-section of the electrical connector has a 1 shape, a T shape, or an I-beam shape.

16. The inkjet head assembly of claim 1, further comprising an oxide film formed on the top and bottom of the package part and a portion where the via is formed.

17. An inkjet head assembly, comprising:
an inkjet head plate including an ink path;
a piezoelectric actuator facing a pressure chamber in the inkjet head plate and providing driving force for ejecting ink to a nozzle from the pressure chamber;
a package part constituted by a silicon layer where a via penetrating the top and bottom and a glass layer bonding the silicon layer and the inkjet head plate to each other, and moving ink introduced from the outside to an inlet of the inkjet head plate; and
an electrical connector filled in the via and electrically connected with the piezoelectric actuator.

18. A method for manufacturing an inkjet head assembly, comprising:
forming an ink path in an inkjet head plate;
forming a piezoelectric actuator providing driving force for ejecting ink to a nozzle in a pressure chamber of the inkjet head plate to face the pressure chamber;
processing a package part to include a path moving ink introduced from the outside to an inlet of the inkjet head plate and a via penetrating the top and bottom;
forming an electrical connector in the via to electrically connect with the piezoelectric actuator; and
stacking and bonding the package part onto the inkjet head plate.

19. The method of claim 18, wherein the processing of the package part forms the path and the via by etching a silicon wafer.

20. The method of claim 18, wherein the processing of the package part etches the via to have a shape of a vertical hole having a constant diameter or an inclined hole having a diameter gradually increasing toward the bottom of the package part.

21. The method of claim 18, wherein the processing of the package part forms the path and the via by a DRIE (deep reactive-ion etching) process.

22. The method of claim 18, further comprising:
processing an intermediate layer to form a communication hole being in communication with the via and a receiver receiving the piezoelectric actuator; and
stacking and bonding the package part onto the intermediate layer.

23. The method of claim 22, wherein the bonding of the intermediate layer and the package part is performed by using anodic bonding or glass frit bonding, polymer bonding, low-temperature silicon direct bonding using plasma, or eutectic bonding.

24. The method of claim 22, wherein the processing of the intermediate layer is performed by a sand blasting or etching process.

25. The method of claim 22, wherein the processing of the intermediate layer includes:
forming the receiver to have a depth equal to a value acquired by adding the thickness of the piezoelectric actuator to a processing error towards the top of the bottom of the intermediate layer; and
forming the communication hole connecting a part of the top of the receiver with the via.

26. The method of claim 18, further comprising:
forming an oxide film on the top and bottom of the package part and the side of the via; and
removing an oxide film from the bottom of the package part.

27. The method of claim 26, wherein the removing of the oxide film is performed by using a chemical mechanical planarization (CMP) process.

28. The method of claim 18, wherein the forming of the electrical connector fills the via with metal by using electroplating.

29. The method of claim 18, further comprising forming a connection member electrically connecting the piezoelectric actuator with the electrical connector.
